(19) United States
(12) Patent Application Publication
(10) Pub. No.: US 2007/0188194 A1
(43) Pub. Date: Aug. 16, 2007

(54) Level shifter circuit and method thereof

(75) Inventors: Hui-kap Yang, Hwaseong-si (KR); Young-gu Kang, Seoul (KR); Ki-chul Chun, Suwon-si (KR); Eun-sung Seo, Seoul (KR); Mi-jo Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co: Ltd.

(21) Appl. No.: 11/700,907

(22) Filed: Feb. 1, 2007

(30) Foreign Application Priority Data
Feb. 15, 2006 (KR) 10-2006-0014742
May 4, 2006 (KR) 10-2006-0040391

(51) Int. Cl. H03K 19/0175

(52) U.S. Cl. 326/80

(57) ABSTRACT

A level shifter circuit and method thereof are provided. The example level shifter circuit may include a pull-up drive unit driving an output node from a first voltage to a second voltage in response to an input signal, a target voltage for the second voltage higher than a target voltage for the first voltage and the input signal based on the first voltage and a third voltage and a pull-down drive unit driving the output node to the third voltage in response to the input signal, the pull-up and pull-down drive units adjusting current levels of at least one of a pull-up current flowing through the pull-up drive unit and a pull-down current flowing through the pull-down drive unit based on whether the pull-up drive unit and the pull-down drive unit are operating concurrently. The example method may include pull-up driving an output node from a first voltage to a second voltage in response to an input signal, a target voltage for the second voltage higher than a target voltage for the first voltage and the input signal based on the first voltage and a third voltage, pull-down driving the output node to the third voltage in response to the input signal, determining whether the pull-up and pull-down driving operations are performed concurrently and adjusting current levels of at least one of a pull-up current and a pull-down current based on the determining step.

This application claims the benefit of Korean Patent Application No. 10-2006-0040391, filed on May 4, 2006, and Korean Patent Application No. 10-2006-0014742, filed on Feb. 15, 2006, in the Korean Intellectual Property Office, the disclosure of which is incorporated herein in its entirety by reference.

### BACKGROUND OF THE INVENTION

1. Field of the Invention

Example embodiments of the present invention relate generally to a level shifter circuit and method thereof, and more particularly to a level shifter circuit and method of reducing leakage current.

2. Description of the Related Art

As power consumption of a semiconductor device (e.g., a dynamic random access memory (DRAM)) decreases, an external supply voltage may be reduced. Accordingly, a level shifter circuit for transforming a lower voltage to a higher voltage may be used to provide a lower external voltage to an internal circuit of the semiconductor device using the “boosted” voltage. Thus, the level shifter circuit may be an interface between circuits using different power supply voltages.

FIG. 1 is a diagram of a conventional semiconductor device 100 including a level shifter circuit 120. The semiconductor device 100 may include a first logic circuit 110, the level shifter circuit 120 and a second logic circuit 140. The semiconductor device 100 may be a wordline driver for driving wordlines of a semiconductor memory device.

Referring to FIG. 1, the first logic circuit 110 may include an inverter 112 receiving a first voltage VDD (e.g., a lower power supply voltage, such as 1.1V) and a ground voltage VSS. The first voltage VDD may be an internal voltage of the semiconductor device 100. The inverter 112 may invert an input signal IN having the first voltage VDD, supplied from an external source, to generate an input signal INL1 input to the level shifter circuit 120. The level shifter circuit 120 may include PMOS transistors 122 and 124, NMOS transistors 126 and 130, and an inverter 128 receiving the first voltage VDD and the ground voltage VSS. The gate of the PMOS transistor 122 may be coupled to the drain of the PMOS transistor 124 and the gate of the PMOS transistor 124 may be coupled to the drain of the PMOS transistor 122.

Referring to FIG. 1, a second voltage VPP (e.g., a higher power supply voltage, such as 2V) may be applied to the sources of the PMOS transistors 122 and 124 and the ground voltage VSS may be applied to the sources of the NMOS transistors 126 and 130. The inverter 128 may be connected between the gate of the NMOS transistor 126 and the gate of the NMOS transistor 130. The level shifter circuit 120 may convert the input signal INL1 having the first voltage VDD to an output signal OUTL1 having the second voltage VPP.

Referring to FIG. 1, the second logic circuit 140 may include a PMOS transistor 142 and an NMOS transistor 144, which may be arranged as an inverter. The second voltage VPP may be applied to the source of the PMOS transistor 142 and the ground voltage VSS may be applied to the source of the NMOS transistor 144. The second logic circuit 140 may invert the output signal OUTL1 having the second voltage VPP and ground voltage VSS to generate an output signal OUT at the second voltage VPP and ground voltage VSS.

Conventional operation of the level shifter circuit 120 of FIG. 1 will now be described in greater detail.

In conventional operation of the level shifter circuit 120 of FIG. 1, if the input signal INL1 transitions from the ground voltage VSS to the first voltage VDD, the NMOS transistor 126 may be turned on and the NMOS transistor 130 may be turned off. A first pull-down current ID11 may flow through the turned on NMOS transistor 128, and thus the potential of an internal node N11 may be decreased. Here, a first pull-up current IU11 may be supplied to the internal node N11 through the PMOS transistor 122 turned on by the potential of an output node N21 before the input signal INL1 is transitioned to the first voltage VDD, and thus the potential of the internal node N11 may decrease relatively slowly to the ground voltage VSS.

In conventional operation of the level shifter circuit 120 of FIG. 1, if the potential of the internal node N11 falls below a voltage obtained by subtracting a threshold voltage of the PMOS transistor 124 from the second voltage VPP, the PMOS transistor 124 may be turned on. Accordingly, a second pull-up current IU21 may flow to the output node N21 through the turned on PMOS transistor 124, and the potential of the output node N21 may increase to the second voltage VPP. The PMOS transistor 122 may be turned off in response to the potential of the output node N21 having the second voltage VPP, and the first pull-up current IU11 may not flow to the internal node N11.

In conventional operation of the level shifter circuit 120 of FIG. 1, if the input signal INL1 is transitioned from the first voltage VDD to the ground voltage VSS, the NMOS transistor 126 may be turned off and the NMOS transistor 130 may be turned on. A second pull-down current ID21 may flow through the turned on NMOS transistor 130, and the potential of the output node N21 may decrease. Here, the second pull-up current IU21 may be supplied to the output node N21 through the PMOS transistor 124 turned on by the potential of the internal node N11 before the input signal INL1 is transitioned to the lower level VSS, and the potential of the output node N21 may decrease relatively slowly to the ground voltage VSS.

In conventional operation of the level shifter circuit 120 of FIG. 1, if the potential of the output node N21 falls below a voltage obtained by subtracting a threshold voltage of the PMOS transistor 122 from the second voltage VPP, the PMOS transistor 122 may be turned on. Accordingly, the first pull-up current IU11 may flow to the internal node N11 through the turned on PMOS transistor 122, and thus the potential of the internal node N11 may be increased to the second voltage VPP. The PMOS transistor 124 may be turned off in response to the potential of the internal node N21 having the second voltage VPP, and the second pull-up current IU21 may not flow to the output node N21.

FIG. 2 is a waveform diagram of the output signal OUTL1 of the level shifter circuit 120 of FIG. 1. In particular, FIG. 2 illustrates the waveform of the output signal OUTL1 of the level shifter circuit 120 with respect to time if the first voltage VDD of the input signal INL1 is 1.1V and the second voltage VPP applied to the level shifter circuit 120 is 2V.

Referring to FIG. 2, the output signal OUTL1 may be undergo a delay period. The transition speed of the output signal OUTL1 may be relatively slow because the PMOS transistor 122 and the NMOS transistor 126 (or alternatively the PMOS transistor 124 and the NMOS transistor 130) may be simultaneously or concurrently operated, or turned on, in the level shifting operation of the level shifter circuit 120 of FIG. 1. Thus, leakage current, or through-current, may flow through the PMOS transistor 122 and the NMOS transistor 126 (or alternatively the PMOS transistor 124 and the NMOS transistor 130). In an example, the leakage current may be direct current (DC).

FIG. 3 illustrates a quantity of leakage current corresponding to the waveform of FIG. 2. Referring to FIG. 3, as shown, the leakage current may flow for a relatively long period of time. Accordingly, a relatively high amount of leakage current may be generated in the level shifter circuit 120, which may increase power consumption of the semiconductor device 100.

Leakage current may be reduced within the level shifter circuit 120 of FIG. 1 by increasing the current drive capability of the NMOS transistors 126 and 130 to levels higher than the current drive capability of the PMOS transistors 122 and 124. However, in order to increase the current driver capability of the NMOS transistors 126 and 130, the sizes of the NMOS transistors 126 and 130 may be increased, which may increase an occupied area of the level shifter circuit.

FIG. 4 is a diagram of another conventional semiconductor device 200 including a level shifter circuit 220. The semiconductor device 200 may include a first logic circuit 210, the level shifter circuit 220 and a second logic circuit 240. The semiconductor device 200 may be a wordline driver for driving wordlines of a semiconductor memory device.

Referring to FIG. 4, the first logic circuit 210 may include a PMOS transistor 212 and an NMOS transistor 214 forming an inverter, and an inverter 216 and an NMOS transistor 218 forming a latch circuit. The first voltage VDD may be applied to the source of the PMOS transistor 212 and the ground voltage VSS may be applied to the source of the NMOS transistor 214. The inverter 216 may receive the first voltage VDD and the ground voltage VSS as a power source, and the ground voltage VSS may be applied to the source of the NMOS transistor 218. The first logic circuit 210 may invert an active lower power-up signal VCCHB twice to generate an input signal INL2 input to the level shifter circuit 220. The power-up signal VCCHB may indicate the supply or a level of first and second voltages VDD and VPP to the semiconductor device 200.

Referring to FIG. 4, the level shifter circuit 220 may include PMOS transistors 222 and 224, NMOS transistors 226 and 228 having gates to which the second voltage VPP may be applied, NMOS transistors 230 and 234, and an inverter 232 receiving the first voltage VDD and the ground voltage VSS. The gate of the PMOS transistor 222 may be coupled to the drain of the PMOS transistor 224 and the gate of the PMOS transistor 224 may be coupled to the drain of the PMOS transistor 222.

Referring to FIG. 4, the second voltage VPP may be applied to the sources of the PMOS transistors 222 and 224 and the ground voltage VSS may be applied to the sources of the NMOS transistors 230 and 234. The inverter 232 may be connected between the gate of the NMOS transistor 230 and the gate of the NMOS transistor 234. The level shifter circuit 220 may convert the input signal INL2 at the first voltage VDD to an output signal OUTL2 at the second voltage VPP.

Referring to FIG. 4, the second logic circuit 240 may include an inverter 242 receiving the second voltage VPP and the ground voltage VSS. The second logic circuit 240 may invert the output signal OUTL2 having the second voltage VPP and the ground voltage VSS to generate an output signal OUT having the second voltage VPP and the ground voltage VSS.

FIG. 5 is a graph illustrating the second voltage VPP and the first voltage VDD applied to the semiconductor device 200 of FIG. 4. Referring to FIG. 5, a time interval TI in which the second voltage VPP may be lower than the first voltage VDD may occur before the second voltage VPP applied to the semiconductor device 200 of FIG. 4 reaches a target voltage VPP. The time interval TI may indicate a power-up interval or a deep power down mode exit interval in a power supply interval of the semiconductor device 200. The power-up interval may correspond to a period from a time when an external voltage may be applied to the semiconductor device 200 to a time when the semiconductor device 200 generates the target voltage VPP, based on the first voltage VDD generated using the external voltage.

Referring to FIG. 5, the deep power down mode exit interval may occur if the semiconductor device 200 is, for example, a mobile DRAM. The deep power down mode exit interval may correspond to a period from a time when the mobile DRAM is in a deep power down mode to a time when the mobile DRAM may generate the target voltage VPP using the first voltage VDD (e.g., generated based on the external voltage, such as 3V), where the supply of the external voltage may be maintained in the mobile DRAM. In a deep power down mode, the first and second voltages VDD and VPP used in the mobile DRAM may be reduced such that the mobile DRAM may not be operated.

Conventional operation of the level shifter circuit 220 in the time interval TI will now be described in greater detail with reference to FIG. 4.

In conventional operation of the level shifter circuit 220 of FIG. 4, if the input signal INL2 transitions form the first voltage VDD to the ground voltage VSS, the NMOS transistor 230 may be turned off and the NMOS transistor 234 may be turned on. The ON resistance of the NMOS transistor 228 may be relatively large because the second voltage VPP may be lower than the first voltage VDD. Accordingly, the quantity of a second pull-down current ID22 flowing through the turned on NMOS transistors 228 and 234 may be relatively small, and the potential of an output node N22 may be decrease relatively slowly to the ground voltage VSS. Here, a second pull-up current IU22 may be provided to the output node N22 through the PMOS transistor 224 turned on by the potential of an internal node N12 before the input signal INL2 transitions to the ground voltage VSS, and the potential of the output node N22 may decrease to the ground voltage VSS more slowly.

In conventional operation of the level shifter circuit 220 of FIG. 4, if the potential of the output node N22 decreases below a voltage obtained by subtracting a threshold voltage of the PMOS transistor 222 from the second voltage VPP, the PMOS transistor 222 may be turned on. Accordingly, a first pull-up current IU12 may flow to the internal node N12 through the turned on PMOS transistor 222, and the potential of the internal node N12 may increase to the second voltage VPP. The PMOS transistor 224 may be turned off in response to the potential of the internal node N12 at the second voltage VPP, and the second pull-up current IU22 may not flow to the output node N22. Accordingly, the leakage current may be reduced.

In conventional operation of the level shifter circuit 220 of FIG. 4, if the input signal INL2 transitions from the ground voltage VSS to the first voltage VDD, the NMOS transistor 230 may be turned on and the NMOS transistor 234 may be turned off. The ON resistance of the NMOS transistor 226 may be relatively large because the second voltage VPP may, at times, be lower than the first voltage VPP. Accordingly, the quantity of a first pull-down current ID12 flowing through the turned on NMOS transistors 226 and 230 may be relatively small, and the potential of the internal node N12 may decrease relatively slowly to the ground voltage VSS. Here, the first pull-up current IU12 may be provided to the internal node N12 through the PMOS transistor 222 turned on by the potential of the output node N22 before the input signal INL2 transitions to the first voltage VDD, and the potential of the internal node N12 may decrease to the ground voltage VSS more slowly.

In conventional operation of the level shifter circuit 220 of FIG. 4, if the potential of the internal node N12 decreases below a voltage obtained by subtracting a threshold voltage of the PMOS transistor 224 from the second voltage VPP, the PMOS transistor 224 may be turned on. Accordingly, the second pull-up current IU22 may flow to the output node N22 through the turned on PMOS transistor 224, and the potential of the output node N22 may be increased to the second voltage VPP. The PMOS transistor 222 may be turned off in response to the potential of the output node N22 at the second voltage VPP, and the first pull-up current IU12 may not flow to the internal node N12. Accordingly, the leakage current may be reduced.

As described above, the speed of the initial operation (i.e., a signal transition speed) of the level shifter circuit 220 if the “higher” second voltage VPP is lower than the “lower” first voltage VDD may be slow because of an operation of the NMOS transistors 226 and 228. Thus, a transition time of the output signal OUTL2 of the level shifter circuit 220 may be increased, or conversely, the transition speed of the output signal OUTL2 may be reduced.

### SUMMARY OF THE INVENTION

An example embodiment of the present invention is directed to a level shifter circuit, including a pull-up drive unit driving an output node from a first voltage to a second voltage in response to an input signal, a target voltage for the second voltage higher than a target voltage for the first voltage and the input signal based on the first voltage and a third voltage and a pull-down drive unit driving the output node to the third voltage in response to the input signal, the pull-up and pull-down drive units adjusting current levels of at least one of a pull-up current flowing through the pull-up drive unit and a pull-down current flowing through the pull-down drive unit based on whether the pull-up drive unit and the pull-down drive unit are operating concurrently.

Another example embodiment of the present invention is directed to a method of level shifting, including pull-up driving an output node from a first voltage to a second voltage in response to an input signal, a target voltage for the second voltage higher than a target voltage for the first voltage and the input signal based on the first voltage and a third voltage, pull-down driving the output node to the third voltage in response to the input signal, determining whether the pull-up and pull-down driving operations are performed concurrently and adjusting current levels of at least one of a pull-up current and a pull-down current based on the determining step.

Another example embodiment of the present invention is directed to a level shifter circuit capable of reducing a transition time of an output signal during a transition of an input signal at a lower voltage to the output signal at a higher voltage.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a diagram of a conventional semiconductor device including a level shifter circuit.

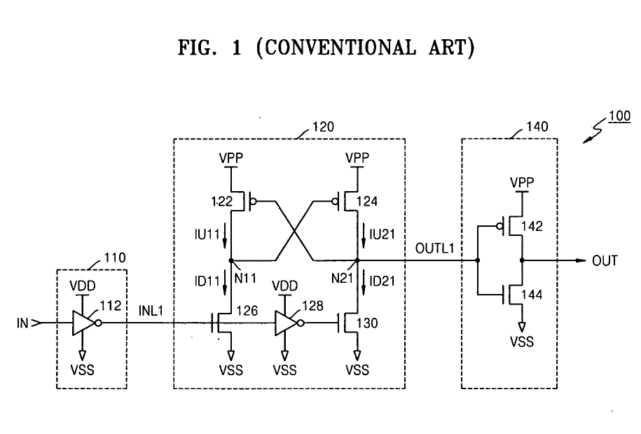

FIG. 2 is a waveform diagram of an input signal and an output signal of the level shifter circuit of FIG. 1.

FIG. 3 illustrates a quantity of leakage current corresponding to the waveform of FIG. 2.

FIG. 4 is a diagram of another conventional semiconductor device including a level shifter circuit.

FIG. 5 is a graph illustrating a voltage VPP and a voltage VDD applied to the semiconductor device of FIG. 4.

FIG. 6 is a diagram of a semiconductor device including a level shifter circuit according to an example embodiment of the present invention.

FIG. 7 illustrates the waveform of an output signal OUTS1 of a level shifter circuit according to another example embodiment of the present invention.

FIG. 8 illustrates a waveform of the leakage current with respect to time corresponding to FIG. 7 according to another example embodiment of the present invention.

FIG. 9 is a diagram of another semiconductor device including a level shifter circuit according to another example embodiment of the present invention.

FIG. 10 is a diagram of another semiconductor device including a level shifter circuit according to another example embodiment of the present invention.

FIG. 11 illustrates voltage levels of the external voltage VEXT, the first voltage VDD and the second voltage VPP over time within the semiconductor device of FIG. 10 according to another example embodiment of the present invention.

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

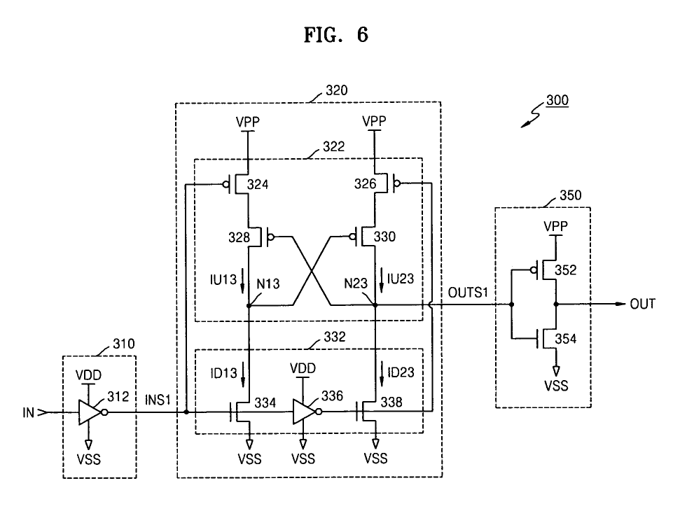

FIG. 6 is a diagram of a semiconductor device 300 including a level shifter circuit according to an example embodiment of the present invention. In the example embodiment of FIG. 6, the semiconductor device 300 may include a first logic circuit 310, a level shifter circuit 320 and a second logic circuit 350. In an example, the semiconductor device 300 may be a wordline driver for driving wordlines of a semiconductor memory device.

In the example embodiment of FIG. 6, the first logic circuit 310 may include an inverter 312 receiving a first voltage VDD (e.g., 1.1V) and a ground voltage VSS. The inverter 312 may invert an input signal IN, which may be supplied from an external device, and may be powered by the first voltage VDD corresponding to an internal voltage of the semiconductor device 300, to generate an input signal INS1 input to the level shifter circuit 320.

In the example embodiment of FIG. 6, the level shifter circuit 320 may include a pull-up drive unit 322 and a pull-down drive unit 332. The level shifter circuit 320 may convert the input signal INS1 at the first voltage VDD into an output signal OUTS1 at a second voltage VPP (e.g., higher than the first voltage VDD).

In the example embodiment of FIG. 6, the pull-up drive unit 322 may include first, second, third and fourth PMOS transistors 324, 326, 328 and 330. In an example, the third and fourth PMOS transistors may form a latch circuit. The first PMOS transistor 324 may include a source to which the second voltage VPP is applied and a gate to which the input signal INS1 is input. The second PMOS transistor 326 may include a source to which the second voltage VPP is applied and a gate to which an inverted signal of the input signal INS1 is input. The third PMOS transistor 328 may include a source connected to the drain of the first PMOS transistor 324, a gate connected to an output node N23, and a drain connected to an internal node N13. The fourth PMOS transistor 330 may include a source connected to the drain of the second PMOS transistor 326, a gate connected to the drain of the third PMOS transistor 328 and a drain connected to the output node N23.

In the example embodiment of FIG. 6, the pull-up drive unit 322 may drive (e.g., pull-up) the output node N23 to the second voltage VPP, which may be higher than the first voltage VDD, in response to the input signal INS1 having the first voltage VDD and the ground voltage VSS and may generate the output signal OUTS1 at the second voltage VPP. The pull-up drive unit 322 may reduce a level of pull-up currents (e.g., IU13 and IU23) flowing through the pull-up drive unit 322 in response to the input signal INS1 if the pull-up drive unit 322 and the pull-down drive unit 332 are operated, or enabled, concurrently (e.g., simultaneously). The pull-up drive unit 322 may drive the signal at the internal node N13, which may correspond to an inverted signal of the signal at the output node N23, to the second voltage VPP in response to the input signal INS1.

In the example embodiment of FIG. 6, the first PMOS transistor 324 of the pull-up drive unit 322 may reduce a level of a first pull-up current IU13, which may be a pull-up current flowing to the internal node N13, in response to the input signal INS1. The second PMOS transistor 326 of the pull-up drive unit 322 may reduce a level of a second pull-up current IU23, which may be another pull-up current flowing to the output node N23, in response to the inverted signal of the input signal INS1.

In the example embodiment of FIG. 6, the pull-down drive unit 332 may include a first NMOS transistor 334, an inverter 336 and a second NMOS transistor 338. The first NMOS transistor 334 may include a drain connected to the drain of the third PMOS transistor 328, a gate receiving the input signal INS1, and a source to which the ground voltage VSS is applied. The inverter 336 may include an input terminal connected to the gate of the first NMOS transistor 334 and may receive, as a power source, the first voltage VDD and the ground voltage VSS. The second NMOS transistor 338 may include a drain connected to the drain of the fourth PMOS transistor 330, a gate connected to the output terminal of the inverter 336, and a source to which the ground voltage VSS is applied.

In the example embodiment of FIG. 6, the pull-down drive unit 332 may drive (e.g., pull-down) the output node N23 to the ground voltage VSS in response to the input signal INS1 and may generate the output signal OUTS1 at the ground voltage VSS. The pull-down drive unit 332 may drive the signal at the internal node N13, which may correspond to the inverted signal of the signal at the output node N23, to the ground voltage VSS in response to the input signal INS1.

In the example embodiment of FIG. 6, the second logic circuit 350 may include a PMOS transistor 352 and an NMOS transistor 354. In an example, the PMOS transistor 352 and the NMOS transistor 354 may form an inverter. The second voltage VPP may be applied to the source of the PMOS transistor 352 and the ground voltage VSS may be applied to the source of the NMOS transistor 354. The second logic circuit 350 may invert the output signal OUTS1 having the second voltage VPP and the ground voltage VSS to generate an output signal OUT having the second voltage VPP and the ground voltage VSS.

Example operation of the level shifter circuit 320 of FIG. 6 will now be described in greater detail.

In example operation of the level shifter circuit 320 of FIG. 6, if the input signal INS1 is transitioned from the ground voltage VSS to the first voltage VDD, the first NMOS transistor 334 may be turned on, the second NMOS transistor 338 may be turned off and the second PMOS transistor 326 may be turned on. Here, the first PMOS transistor 324 may not be turned off because its gate-to-source voltage Vgs (e.g., VDD-VPP) may be lower than a threshold voltage (e.g., −0.7V) of the first PMOS transistor 324, and the first PMOS transistor 324 may further have a relatively large ON resistance Ron. Accordingly, a level of the first pull-up current IU13, which flows through the turned on first PMOS transistor 324 and the third PMOS transistor 328 turned on by the potential of the output node N23 before the input signal INS1 is transitioned to the first voltage VDD, may be reduced. Thus, the potential of the internal node N13 may decrease, relatively rapidly, to the ground voltage VSS based on a first pull-down current ID13 flowing through the turned on first NMOS transistor 334.

In example operation of the level shifter circuit 320 of FIG. 6, if the potential of the internal node N13 is decreased below a voltage obtained by subtracting a threshold voltage of the fourth PMOS transistor 330 from the second voltage VPP, the fourth PMOS transistor 330 may be turned on. Accordingly, the second pull-up current IU23 may flow to the output node N23 through the turned on second PMOS transistor 326 and the turned on fourth PMOS transistor 330. Thus, the potential of the output node N23 may be increased to the second voltage VPP. The third PMOS transistor 328 may be turned off in response to the potential of the output node N23 at the second voltage VPP, and the first pull-up current IU13 may be reduced (e.g., may not flow) to the internal node N13. Accordingly, a leakage current may be reduced.

In example operation of the level shifter circuit 320 of FIG. 6, if the input signal INS1 is transitioned from the first voltage VDD to the ground voltage VSS, the first NMOS transistor 334 may be turned off, the first PMOS transistor 324 may be turned on and the second NMOS transistor 338 may be turned on. Here, the second PMOS transistor 326 may not be turned off because its gate-to-source voltage Vgs (e.g., VDD-VPP) may be lower than a threshold voltage of the second PMOS transistor 326, and the second PMOS transistor 326 may further have a relatively large ON resistance Ron. Accordingly, a level of the second pull-up current IU23, which flows through the turned on second PMOS transistor 326 and the fourth PMOS transistor 330 turned on by the potential of the internal node N13 before the input signal INS1 transitions to the ground voltage VSS, may be reduced. Thus, the potential of the output node N23 may decrease, relatively rapidly, to the ground voltage VSS based on a second pull-down current ID23 flowing through the turned on second NMOS transistor 338.

In example operation of the level shifter circuit 320 of FIG. 6, if the potential of the output node N23 decreases below a voltage obtained by subtracting a threshold voltage of third fourth PMOS transistor 328 from the second voltage VPP, the third PMOS transistor 328 may be turned on. Accordingly, the first pull-up current IU13 may flow to the internal node N13 through the turned on first PMOS transistor 324 and the turned on third PMOS transistor 328, and the potential of the internal node N13 may be increased to the second voltage VPP. The fourth PMOS transistor 330 may be turned off in response to the potential of the internal node N13 at the second voltage VPP, and the second pull-up current IU23 may not flow to the output node N23. Accordingly, leakage current may be reduced.

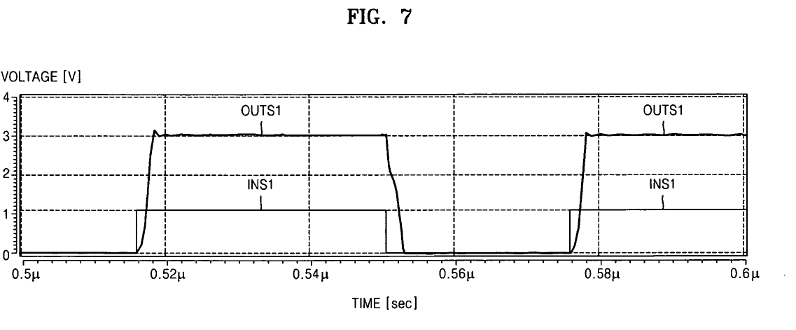

FIG. 7 illustrates the waveform of the output signal OUTS1 of the level shifter circuit 320 according to another example embodiment of the present invention. In particular, FIG. 7 illustrates an example where the first voltage VDD of the input signal INS1 may be equal to 1.1V and the second voltage VPP applied to the level shifter circuit 320 may be equal to 3V.

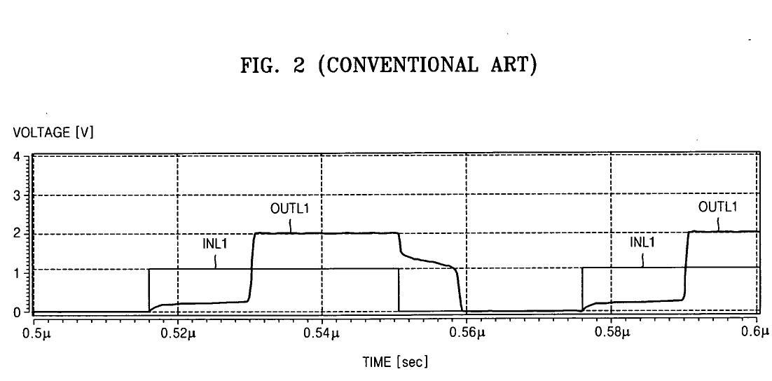

In the example embodiment of FIG. 7, the output signal OUTS1 may increase or decrease to a target voltage at a relatively high rate as compared to the output signal OUTL1 illustrated in conventional FIG. 2. Thus, the transition speed of the output signal OUTS1 may be faster than the transition speed of the output signal OUTL1 illustrated in conventional FIG. 2. The increased transition rate of the output signal OUTS1 of FIG. 7 may be based, at least in part, on reduced leakage current (or through current). As discussed above, the leakage current may be reduced if the first and third PMOS transistors 328 and the first NMOS transistor 334 (or the second and fourth PMOS transistors 326 and 330 and the second NMOS transistor 338) are operated, or turned on, concurrently, in the level shifting operation of the level shifter circuit 320 of FIG. 6.

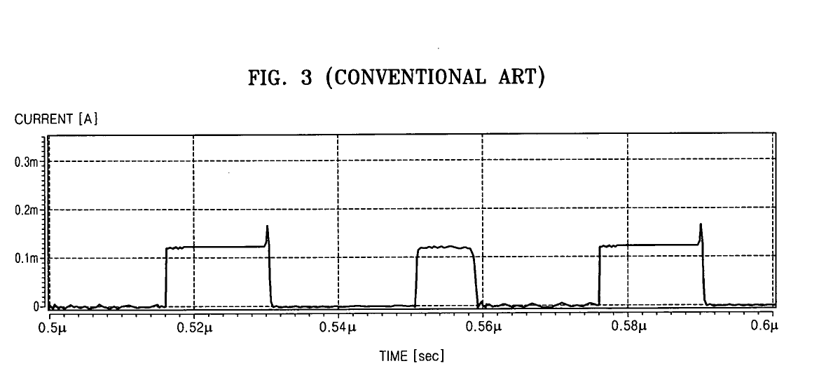

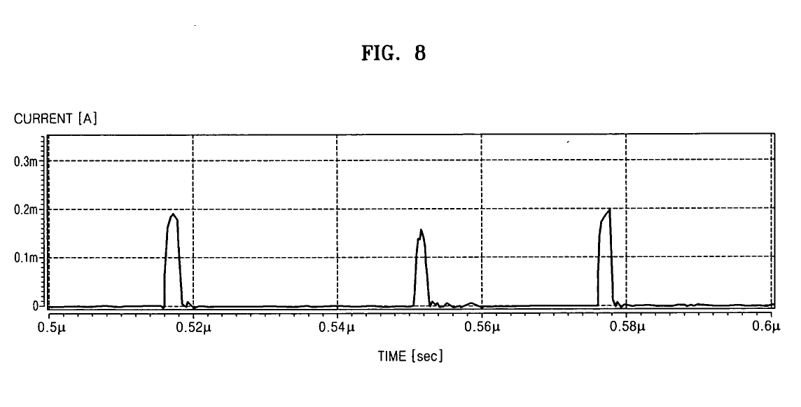

FIG. 8 illustrates a waveform of the leakage current with respect to time corresponding to FIG. 7 according to another example embodiment of the present invention. Accordingly, in an example, the leakage current illustrated in FIG. 8 may be achieved under conditions where the first voltage VDD of the input signal INS1 of the level shifter circuit 320 of FIG. 6 may be 1.1V and the second voltage VPP applied to the level shifter circuit 320 may be 3V. In the example embodiment of FIG. 8, the leakage current may flow for a reduced period of time as compared to conventional FIG. 3, and, accordingly, a level of leakage current may be decreased.

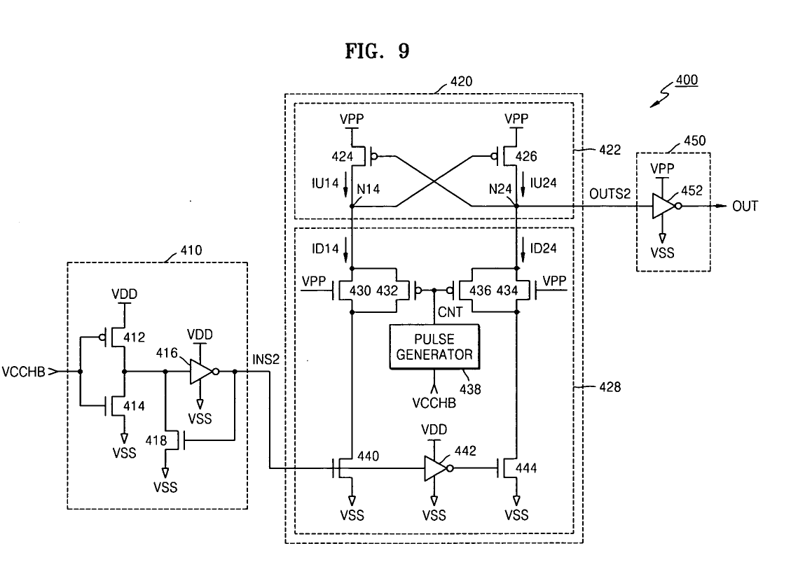

FIG. 9 is a diagram of a semiconductor device 400 including a level shifter circuit 420 according to another example embodiment of the present invention. In the example embodiment of FIG. 9, the semiconductor device 400 may include a first logic circuit 410, the level shifter circuit 420 and a second logic circuit 450. In an example, the semiconductor device 400 may be a wordline driver for driving wordlines of a semiconductor memory device.

In the example embodiment of FIG. 9, the first logic circuit 410 may include a PMOS transistor 412 and an NMOS transistor 414 forming an inverter, and an inverter 416 and an NMOS transistor 418 forming a latch circuit. The first voltage VDD may be applied to the source of the PMOS transistor 412 and the ground voltage VSS may be applied to the source of the NMOS transistor 414. The inverter 416 may receive the first voltage VDD and the ground voltage VSS, which may be internal voltages of the semiconductor device 400, as its power source. The ground voltage VSS may be applied to the source of the NMOS transistor 418. In an example, the first logic circuit 410 may invert an active lower power-up signal VCCHB twice to generate an input signal INS2, which may be input to the level shifter circuit 420. The power-up signal VCCHB may indicate the supply of first and second voltages VDD and VPP to the semiconductor device 400. The semiconductor device 400 may generate the second voltage VPP based on the first voltage VDD.

In the example embodiment of FIG. 9 ,the level shifter circuit 420 may include a pull-up drive unit 422 and a pull-down drive unit 428. The level shifter circuit 420 may convert the input signal INS2 at the first voltage VDD into an output signal OUTS2 at the second voltage VPP. The input signal INS2 may be obtained by delaying the power-up signal VCCHB by a given delay period.

In the example embodiment of FIG. 9, the pull-down drive unit 428 may include a first NMOS transistor 430, a first PMOS transistor 432, a second NMOS transistor 434, a second PMOS transistor 436, a pulse generator 438, a third NMOS transistor 440, an inverter 442 and a fourth NMOS transistor 444.

In the example embodiment of FIG. 9, the first NMOS transistor 430 may include a drain connected to an internal node N14 and a gate to which the second voltage VPP is applied. The first PMOS transistor 432 may include a source connected to the drain of the first NMOS transistor 430, a gate receiving a pull-down control signal CNT generated by the pulse generator 438 and a drain connected to the source of the first NMOS transistor 430. The second NMOS transistor 434 may include a drain connected to an output node N24 and a gate to which the second voltage VPP is applied. The second PMOS transistor 436 may include a source connected to the drain of the second NMOS transistor 434, a gate receiving the pull-down control signal CNT generated by the pulse generator 438, and a drain connected to the source of the second NMOS transistor 434.

In the example embodiment of FIG. 9, the third NMOS transistor 440 may include a drain connected to the source of the first NMOS transistor 430, a gate receiving the input signal INS2, and a source to which the ground voltage VSS is applied. The inverter 442 may include an input terminal connected to the gate of the third NMOS transistor 440, and may receive, as a power source, the first voltage VDD and the ground voltage VSS. The fourth NMOS transistor 444 may include a drain connected to the source of the second NMOS transistor 434, a gate connected to the output terminal of the inverter 442 and a source to which the ground voltage VSS is applied.

In the example embodiment of FIG. 9, the pull-down drive unit 428 may drive (e.g., pull down) the output node N24 to the ground voltage VSS in response to the input signal INS2 having the first voltage VDD and the ground voltage VSS, and may generate the output signal OUTS2 having the ground voltage VSS. The pull-down drive unit 428 may increase a level of initial pull-down currents ID14 and ID24 flowing through the pull-down drive unit 428 in response to the input signal INS2 if the pull-up drive unit 422 and the pull-down drive unit 428 are concurrently (e.g., simultaneously) operated or enabled. The pull-down drive unit 428 may drive the signal at the internal node N14, which may correspond to the inverted signal of the signal at the output node N24, to the ground voltage VSS in response to the input signal INS2.

In the example embodiment of FIG. 9, the pulse generator 438 of the pull-down drive unit 428 may generate the pull-down control signal CNT in response to the power-up signal VCCHB. Thus, the pulse generator 438 may generate the pull-down control signal CNT corresponding to a pulse signal at the ground voltage VSS for a given delay period in response to the power-up signal VCCHB. The pulse generator 438 may be operated in response to the input signal INS2.

In the example embodiment of FIG. 9, the first PMOS transistor 432 of the pull-down drive unit 428 may increase a first initial pull-down current ID14, which may be an initial pull-down current output from the internal node N14, in response to the pull-down control signal CNT being set to the ground voltage VSS (e.g., a “lower” voltage level). Thus, the first PMOS transistor 432 may be turned on in response to the pull-down control signal CNT set to the ground voltage VSS, and thus the first PMOS transistor 432 may reduce the resistance of a pull-down current path through which the first initial pull-down current ID14 flows if the pull-down drive unit 428 performs an initial operation (e.g., if the second voltage VPP applied to the level shifter circuit 420 is lower than the first voltage VDD applied to the level shifter circuit 420). Accordingly, a level of the first initial pull-down current ID14 may be increased.

In the example embodiment of FIG. 9, the second PMOS transistor 436 of the pull-down drive unit 428 may increase a second initial pull-down current ID24, which may be another initial pull-down current output from the output node N24, in response to the pull-down control signal CNT. Thus, the second PMOS transistor 436 may be turned on in response to the pull-down control signal CNT being set to the ground voltage VSS. Thus, the second PMOS transistor 436 may reduce the resistance of a pull-down current path through which the second initial pull-down current ID24 flows when the pull-down drive unit 428 performs the initial operation (e.g., if the second voltage VPP applied to the level shifter circuit 420 is lower than the first voltage VDD applied to the level shifter circuit 420). Accordingly, a level of the second initial pull-down current ID24 may be increased.

In the example embodiment of FIG. 9, the pull-up drive unit 422 may include a third PMOS transistor 424 and a fourth PMOS transistor 426. In an example, the third and fourth PMOS transistors 424 and 426 may collectively constitute a latch circuit. The third PMOS transistor 424 may include a source to which the second voltage VPP is applied, a gate connected to the output node N24 and a drain connected to the internal node N14. The fourth PMOS transistor 426 may include a source to which the second voltage VPP is applied, a gate connected to the internal node N14 and a drain connected to the output node N24.

In the example embodiment of FIG. 9, the pull-up drive unit 422 may drive (e.g., pull up) the output node N24 to the second voltage VPP (e.g., higher than the first voltage VDD) in response to the input signal INS2, and may generate the output signal OUTS2 having the second voltage VPP. The pull-up drive unit 422 may drive the signal at the internal node N14, which may correspond to the inverted signal of the signal at the output node N24, to the second voltage VPP, in response to the input signal INS2.

In the example embodiment of FIG. 9, the second logic circuit 450 may include an inverter 452 receiving, as a power source, the second voltage VPP and the ground voltage VSS. The second logic circuit 450 may invert the output signal OUTS2 having the second voltage VPP and the ground voltage VSS to generate an output signal OUT having the second voltage VPP and the ground voltage VSS.

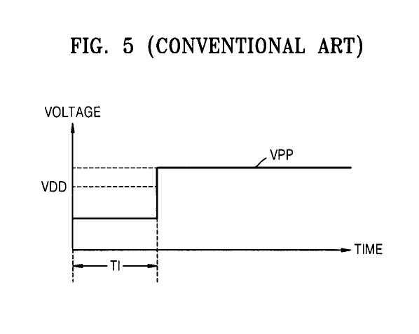

Example operation of the level shifter circuit 420 in the time interval TI from FIG. 5 will now be described in greater detail with respect to the example embodiment of FIG. 9.

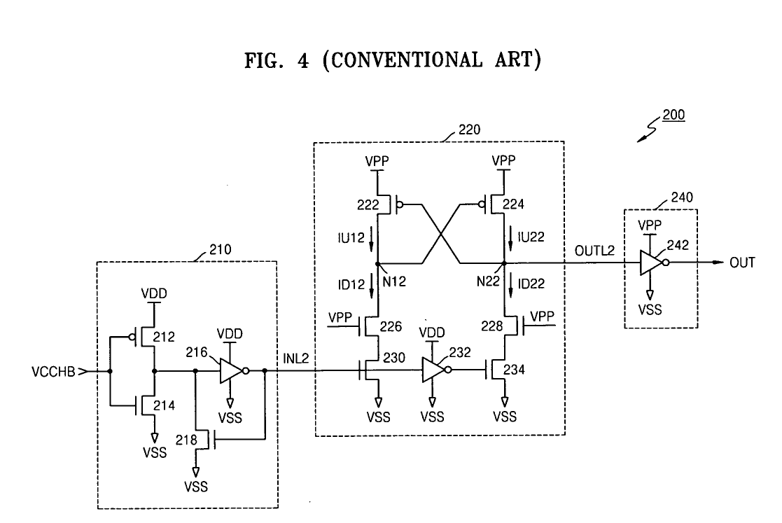

In example operation of the level shifter circuit 420 of FIG. 9, within the time interval TI, if the input signal INS2 transitions from the first voltage VDD to the ground voltage VSS, the third NMOS transistor 440 may be turned off and the fourth NMOS transistor 444 may be turned on. In an example, the ON resistance of the second NMOS transistor 434 may be relatively large because the second voltage VPP applied to the level shifter circuit 420 may be lower than the first voltage VDD applied to the level shifter circuit 420. Here, the pulse generator 438 may generate the pull-down control signal CNT corresponding to a pulse signal having the ground voltage VSS in response to the power-up signal VCCHB generating the input signal INS2, and thus the second PMOS transistor 436 may be turned on. Accordingly, the second initial pull-down current ID24 flowing through the turned on second PMOS transistor 436, the turned on second NMOS transistor 434 and the turned on fourth NMOS transistor 444 may be increased because the resistance of the turned on second PMOS transistor 436 and the turned on second NMOS transistor 434 may be decreased. Accordingly, the potential of the output node N24 may decrease, relatively rapidly, to the ground voltage VSS. Here, the second initial pull-down current ID24 may be increased even though the second pull-up current IU24 may be supplied to the output node N24 through the fourth PMOS transistor 426 turned on by the potential of the internal node N14 before the input signal INS2 is transitioned to the ground voltage VSS. Thus, the potential of the output node N24 may be decreased to the ground voltage VSS faster than the potential of the output node of the conventional level shifter circuit 220 illustrated in conventional FIG. 4.

In example operation of the level shifter circuit 420 of FIG. 9, within the time interval TI, if the potential of the output node N24 is decreased below a voltage obtained by subtracting a threshold voltage of the third PMOS transistor 424 from the second voltage VPP, the third PMOS transistor 424 may be turned on. Accordingly, a first pull-up current IU14 flowing to the internal node N14 through the turned on third PMOS transistor 424, and thus the potential of the internal node N14, may be increased to the second voltage VPP. The fourth PMOS transistor 426 may be turned off in response to the potential of the internal node N14 at the second voltage VPP, and thus the second pull-up current IU24 may be reduced to the output node N24. Accordingly, leakage current may be reduced.

In example operation of the level shifter circuit 420 of FIG. 9, within the time interval TI, if the input signal INS2 is transitioned from the ground voltage VSS to the first voltage VDD, the third NMOS transistor 440 may be turned on and the fourth NMOS transistor 444 may be turned off. In an example, the ON resistance of the first NMOS transistor 430 may be relatively large because the second voltage VPP applied to the level shifter circuit 420 may be lower than the first voltage VDD applied to the level shifter circuit 420. Here, the pulse generator 438 may generate the pull-down control signal CNT corresponding to a pulse signal having the ground voltage VSS in response to the power-up signal VCCHB generating the input signal INS2, and thus the first PMOS transistor 432 may be turned on. Accordingly, the first initial pull-down current ID14 flowing through the turned on first PMOS transistor 432, the turned on first NMOS transistor 430 and the turned on third NMOS transistor 440 may be increased because the resistance of the turned on first PMOS transistor 432 and the turned on first NMOS transistor 430 may be decreased. Accordingly, the potential of the internal node N14 may decrease, relatively rapidly, to the ground voltage VSS. Here, the first initial pull-down current ID14 may be increased even though the first pull-up current IU14 is supplied to the internal node N14 through the third PMOS transistor 424 turned on by the potential of the output node N24 before the input signal INS2 is transitioned to the first voltage VDD. Thus, the potential of the internal node N14 may be decreased to the ground voltage VSS faster than the potential of the output node of the conventional level shifter circuit 220 illustrated in conventional FIG. 4.

In example operation of the level shifter circuit 420 of FIG. 9, within the time interval TI, if the potential of the internal node N14 is decreased below a voltage obtained by subtracting a threshold voltage of the fourth PMOS transistor 426 from the second voltage VPP, the fourth PMOS transistor 426 may be turned on. Accordingly, the second pull-up current IU24 flowing to the output node N24 through the turned on fourth PMOS transistor 426, and the potential of the output node N24, may be increased to the second voltage VPP. The third PMOS transistor 424 may be turned off in response to the potential of the output node N24 at the second voltage VPP, and thus the first pull-up current IU14 may be reduced (e.g., may not flow) to the internal node N14. Accordingly, leakage current may be reduced.

As described above with respect to the example embodiment of FIG. 9, the speed of the initial operation (e.g., a signal transition speed) of the level shifter circuit 420 may be increased if the second voltage VPP applied to the level shifter circuit 420 is lower than the first voltage VDD applied to the level shifter circuit because of the first and second PMOS transistors 432 and 436. Thus, the transition time of the output signal OUTS2 of the level shifter circuit 420 may be decreased, or conversely, the transition speed of the output signal OUTS2 may be increased.

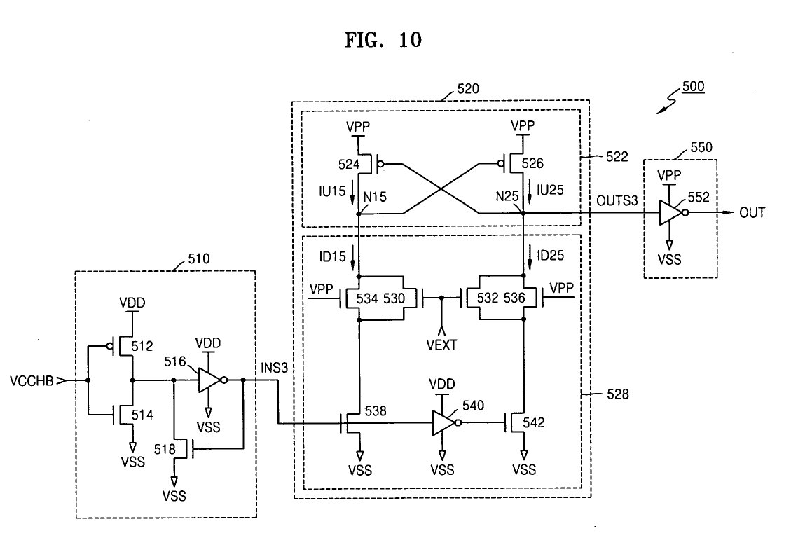

FIG. 10 is a diagram of a semiconductor device 500 including a level shifter circuit 520 according to another example embodiment of the present invention. In the example embodiment of FIG. 10, the semiconductor device 500 may include a first logic circuit 510, the level shifter circuit 520 and a second logic circuit 550. In an example, the semiconductor device 500 may be a wordline driver for driving wordlines of a semiconductor memory device.

In the example embodiment of FIG. 10, the first logic circuit 510 may include a PMOS transistor 512 and an NMOS transistor 514 forming an inverter, and an inverter 516 and an NMOS transistor 518. In an example, the inverter 516 and the NMOS transistor 518 may collectively form a latch circuit. The first voltage VDD may be applied to the source of the PMOS transistor 512 and the ground voltage VSS may be applied to the source of the NMOS transistor 514. The inverter 516 may receive, as a power source, the first voltage VDD and the ground voltage VSS, which may be internal voltages of the semiconductor device 500. The ground voltage VSS may be applied to the source of the NMOS transistor 518.

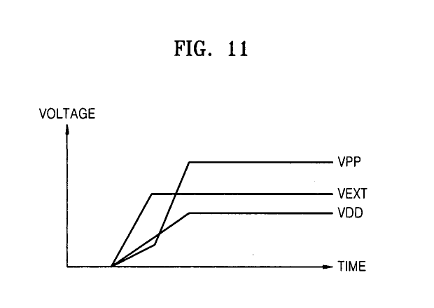

In the example embodiment of FIG. 10, in an example, the first logic circuit 510 may invert the active low power-up signal VCCHB twice to generate an input signal INS3 input to the level shifter circuit 520. The power-up signal VCCHB may indicate the supply of first and second voltages VDD and VPP to the semiconductor device 500. The semiconductor device 500 may generate the second voltage VPP based on the first voltage VDD. The first voltage VDD may be generated based on an external voltage VEXT. The relative voltage levels of the external voltage VEXT, the first voltage VDD and the second voltage VPP with respect to time will now be described with respect to the example embodiment of FIG. 11. Accordingly, FIG. 11 illustrates voltage levels of the external voltage VEXT, the first voltage VDD and the second voltage VPP over time within the semiconductor device 500 of FIG. 10 according to another example embodiment of the present invention.

In the example embodiment of FIG. 10, the level shifter circuit 520 may include a pull-up drive unit 522 and a pull-down drive unit 528. The level shifter circuit 520 may convert the input signal INS3 at the first voltage VDD into an output signal OUTS3 at the second voltage VPP. The input signal INS3 may be obtained by delaying the power-up signal VCCHB by a given delay period.

In the example embodiment of FIG. 10, the pull-down drive unit 528 may include a first NMOS transistor 530, a second NMOS transistor 532, a third NMOS transistor 534, a fourth NMOS transistor 536, a fifth NMOS transistor 538, an inverter 540, and a sixth NMOS transistor 542.

In the example embodiment of FIG. 10, the first NMOS transistor 530 may include a drain connected to an internal node N15 and a gate to which the external voltage VEXT is applied. The second NMOS transistor 532 may include a drain connected to an output node N25 and a gate to which the external voltage VEXT is applied. The third NMOS transistor 534 may include a drain connected to the drain of the first NMOS transistor 530, a gate to which the second voltage VPP is applied and a source connected to the source of the first NMOS transistor 530. The fourth NMOS transistor 536 may include a drain connected to the drain of the second NMOS transistor 532, a gate to which the second voltage VPP is applied and a source connected to the source of the second NMOS transistor 532.

In the example embodiment of FIG. 10, the fifth NMOS transistor 538 may include a drain connected to the source of the third NMOS transistor 534, a gate receiving the input signal INS3 and a source to which the ground voltage VSS is applied. The inverter 540 may include an input terminal connected to the gate of the fifth NMOS transistor 538 and may receive, as a power source, the first voltage VDD and the ground voltage VSS. The sixth NMOS transistor 542 may include a drain connected to the source of the fourth NMOS transistor 536, a gate connected to the output terminal of the inverter 540 and a source to which the ground voltage VSS is applied.

In the example embodiment of FIG. 10, the pull-down drive unit 528 may drive (e.g., pull down) the output node N25 to the ground voltage VSS in response to the input signal INS3 having the first voltage VDD and the ground voltage VSS, and may generate the output signal OUTS3 having the ground voltage VSS. The pull-down drive unit 528 may increase levels of initial pull-down currents ID15 and ID25 flowing through the pull-down drive unit 528 in response to the input signal INS3 if the pull-up drive unit 522 and the pull-down drive unit 528 are concurrently (e.g., simultaneously) operated or enabled. The pull-down drive unit 528 may drive the signal at the internal node N15, which may correspond to the inverted signal of the signal at the output node N25, to the ground voltage VSS in response to the input signal INS3.

In the example embodiment of FIG. 10, the first NMOS transistor 530 of the pull-down drive unit 528 may increase the first initial pull-down current ID15, which may be the initial pull-down currents ID15 output from the internal node N15, in response to the external voltage VEXT. In an example, the external voltage VEXT may be higher than the first voltage VDD or the second voltage VPP, as illustrated in FIG. 11, if the pull-down drive unit 528 performs its initial operation (e.g., if the second voltage VPP applied to the level shifter circuit 520 is lower than the first voltage VDD applied to the level shifter circuit 520), and thus the resistance of a pull-down current path through which the first initial pull-down current ID15 flows may be decreased. Accordingly, the first initial pull-down current ID15 may be increased.

In the example embodiment of FIG. 10, the second NMOS transistor 532 of the pull-down drive unit 528 may increase a second initial pull-down current ID25, which may be the initial pull-down current ID25 output from the output node N25, in response to the external voltage VEXT. In an example, the external voltage VEXT may be higher than the first voltage VDD or the second voltage VPP, as illustrated in FIG. 11, if the pull-down drive unit 528 performs its initial operation (e.g., if the second voltage VPP applied to the level shifter circuit 520 is lower than the first voltage VDD applied to the level shifter circuit 520), and thus the resistance of a pull-down current path through which the second initial pull-down current ID25 flows may be decreased. Accordingly, the second initial pull-down current ID25 may be increased.

In the example embodiment of FIG. 10, the pull-up drive unit 522 may include a first PMOS transistor 524 and a second PMOS transistor 526. In an example, the first and second PMOS transistor 524 and 526 may form a latch circuit. The first PMOS transistor 524 may include a source to which the second voltage VPP is applied, a gate connected to the output node N25 and a drain connected to the internal node N15. The second PMOS transistor 526 may include a source to which the second voltage VPP is applied, a gate connected to the internal node N15 and a drain connected to the output node N25.

In the example embodiment of FIG. 10, the pull-up drive unit 522 may drive (e.g., pull up) the output node N25 to the second voltage VPP (e.g., higher than the first voltage VDD) in response to the input signal INS3, and may generate the output signal OUTS3 having the second voltage VPP. The pull-up drive unit 522 may drive the signal at the internal node N15, which may correspond to the inverted signal of the signal at the output node N25, to the second voltage VPP in response to the input signal INS3.

In the example embodiment of FIG. 10, the second logic circuit 550 may include an inverter 552 receiving, as a power source, the second voltage VPP and the ground voltage VSS. The second logic circuit 550 may invert the output signal OUTS3 having the second voltage VPP and the ground voltage VSS to generate an output signal OUT having the second voltage VPP and the ground voltage VSS.

Example operation of the level shifter circuit 520, within the time interval TI illustrated in FIG. 5, will now be described in greater detail with reference to the example embodiment of FIG. 10.

In example operation of the level shifter circuit 520 of FIG. 10, within the time interval TI of FIG. 5, if the input signal INS3 is transitioned from the first voltage VDD to the ground voltage VSS, the fifth NMOS transistor 538 may be turned off and the sixth NMOS transistor 542 may be turned on. The ON resistance of the fourth NMOS transistor 536 may be relatively large because the second voltage VPP applied to the level shifter circuit 520 may be lower than the first voltage VDD applied to the level shifter circuit 520. However, the second NMOS transistor 532 may be turned on (e.g., strongly turned on) and may have a relatively small ON resistance in response to the external voltage VEXT higher than the second voltage VPP and/or the first voltage VDD while the pull-down drive unit 528 performs its initial operation. Accordingly, the second initial pull-down current ID25 flowing through the turned on second NMOS transistor 532, the turned on fourth NMOS transistor 536 and the turned on sixth NMOS transistor 542 may increase because the resistance of the turned on second NMOS transistor 532 and the turned on fourth NMOS transistor 536 may be decreased. Accordingly, the potential of the output node N25 may be decreased (e.g., rapidly decreased) to the ground voltage VSS. Here, the second initial pull-down current ID25 may be increased even though the second pull-up current IU25 may be supplied to the output node N25 through the second PMOS transistor 526 turned on by the potential of the internal node N15 before the input signal INS3 is transitioned to the ground voltage VSS. Thus, the potential of the output node N25 may decrease to the ground voltage VSS faster than the potential of the output node of the conventional level shifter circuit 220 illustrated in FIG. 4.

In example operation of the level shifter circuit 520 of FIG. 10, within the time interval TI of FIG. 5, if the potential of the output node N25 decreases below a voltage obtained by subtracting a threshold voltage of the first PMOS transistor 524 from the high voltage VPP, the first PMOS transistor 524 may be turned on. Accordingly, a first pull-up current IU15 may flow to the internal node N15 through the turned on first PMOS transistor 524, and thereby, the potential of the internal node N15 may be increased to the second voltage VPP. The second PMOS transistor 526 may be turned off in response to the potential of the internal node N15 at the second voltage VPP, and thereby, the second pull-up current IU25 may be reduced (e.g., may not flow) to the output node N25. Accordingly, leakage current may be reduced.

In example operation of the level shifter circuit 520 of FIG. 10, within the time interval TI of FIG. 5, if the input signal INS3 is transitioned from the ground voltage VSS to the first level VDD, the fifth NMOS transistor 538 may be turned on and the sixth NMOS transistor 542 may be turned off. In an example, the ON resistance of the third NMOS transistor 534 may be relatively large because the second voltage VPP applied to the level shifter circuit 520 may be lower than the first voltage VDD applied to the level shifter circuit 520. However, the first NMOS transistor 530 may be turned on (e.g., strongly turned on) and may have a relatively small ON resistance in response to the external voltage VEXT being higher than the second voltage VPP and/or the first voltage VDD while the pull-down drive unit 528 performs its initial operation. Accordingly, the first initial pull-down current ID15 flowing through the turned on first NMOS transistor 530, the turned on third NMOS transistor 534 and the turned on fifth NMOS transistor 538 may be increased because the resistance of the turned on first NMOS transistor 530 and the turned on third NMOS transistor 534 may be decreased. Accordingly, the potential of the internal node N15 may decrease (e.g., rapidly decrease) to the ground voltage VSS. In an example, the first initial pull-down current ID15 may increase even though the first pull-up current IU15 is supplied to the internal node N15 through the first PMOS transistor 524 turned on by the potential of the output node N25 before the input signal INS3 is transitioned to the first level VDD. Thus, the potential of the internal node N15 may transition (e.g., decrease) to the ground voltage VSS faster than the potential of the output node of the conventional level shifter circuit 220 illustrated in FIG. 4.

In example operation of the level shifter circuit 520 of FIG. 10, within the time interval TI of FIG. 5, if the potential of the internal node N15 decreases below a voltage obtained by subtracting a threshold voltage of the second PMOS transistor 526 from the second voltage VPP, the second PMOS transistor 526 may be turned on. Accordingly, the second pull-up current IU25 may flow to the output node N25 through the turned on second PMOS transistor 526, and thereby, the potential of the output node N25 may transition (e.g., increase) to the second voltage VPP. The first PMOS transistor 524 may be turned off in response to the potential of the output node N25 at the second voltage VPP, and thereby, the first pull-up current IU15 may be reduced (e.g., may not flow) to the internal node N15. Accordingly, leakage current may be reduced.

In example operation of the level shifter circuit 520 of FIG. 10, within the time interval TI of FIG. 5, a speed of the initial operation (e.g., a signal transition speed) of the level shifter circuit 520 may increase if the second voltage VPP applied to the level shifter circuit 520 is lower than the first voltage VDD applied to the level shifter circuit 520 because of the first and second NMOS transistors 530 and 532. Thus, the transition time of the output signal OUTS3 of the level shifter circuit 520 may be decreased, or conversely, the transition speed of the output signal OUTS3 may be increased.

Example embodiments of the present invention being thus described, it will be obvious that the same may be varied in many ways. For example, while above-described example embodiments are directed generally to DRAM devices, other example embodiments of the present invention may be directed to any type of semiconductor device.

Such variations are not to be regarded as a departure from the spirit and scope of example embodiments of the present invention, and all such modifications as would be obvious to one skilled in the art are intended to be included within the scope of the following claims.

What is claimed is:

1. A level shifter circuit, comprising:
a pull-up drive unit driving an output node from a first voltage to a second voltage in response to an input signal, a target voltage for the second voltage higher than a target voltage for the first voltage and the input signal based on the first voltage and a third voltage; and
a pull-down drive unit driving the output node to the third voltage in response to the input signal, the pull-up and pull-down drive units adjusting current levels of at least one of a pull-up current flowing through the pull-up drive unit and a pull-down current flowing through the pull-down drive unit based on whether the pull-up drive unit and the pull-down drive unit are operating concurrently.

2. The level shifter circuit of claim 1, wherein the third voltage is a ground voltage.

3. The level shifter circuit of claim 1, wherein the pull-up drive unit reduces the pull-up current flowing through the pull-up drive unit if the pull-up drive unit and the pull-down drive unit are determined to be operating concurrently.

4. The level shifter circuit of claim 3, wherein the pull-up drive unit drives a first signal at an internal node, which corresponds to an inverted signal of a second signal at the output node, to the second voltage in response to the input signal, and the pull-down drive unit drives the signal at the internal node to the third voltage in response to the input signal.

5. The level shifter circuit of claim 4, wherein the pull-up drive unit includes:
a first PMOS transistor reducing a first pull-up current, which flows to the internal node, in response to the input signal; and
a second PMOS transistor reducing a second pull-up current, which flows to the output node, in response to an inverted signal of the input signal.

6. The level shifter circuit of claim 5, wherein the pull-up drive unit further includes:
a third PMOS transistor having a source connected to a drain of the first PMOS transistor, a gate connected to the output node and a drain connected to the internal node; and
a fourth PMOS transistor having a source connected to a drain of the second PMOS transistor, a gate connected to the drain of the third PMOS transistor and a drain connected to the output node.

7. The level shifter circuit of claim 6, wherein the pull-down drive unit includes:
a first NMOS transistor having a drain connected to the drain of the third PMOS transistor, a gate receiving the input signal and a source to which the third voltage is applied;
an inverter having an input terminal connected to the gate of the first NMOS transistor and using the first voltage and the third voltage as a power source; and
a second NMOS transistor having a drain connected to the drain of the fourth PMOS transistor, a gate connected to an output terminal of the inverter, and a source to which the third voltage is applied.

8. The level shifter circuit of claim 1, wherein the pull-down drive unit increases the pull-down current flowing through the pull-down drive unit if the pull-up drive unit and the pull-down drive unit are determined to be operating concurrently.

9. The level shifter circuit of claim 8, wherein the pull-up drive unit drives a first signal at an internal node, which corresponds to an inverted signal of a second signal at the output node, to the second voltage in response to the input signal, and the pull-down drive unit drives the signal at the internal node to the third voltage in response to the input signal.

10. The level shifter circuit of claim 9, wherein the input signal is obtained by delaying a power-up signal that indicates levels of the first and second voltages to the level shifter circuit.

11. The level shifter circuit of claim 10, wherein the pull-down drive unit includes:
a pulse generator generating a pull-down control signal in response to the power-up signal;
a first PMOS transistor increasing a first pull-down current, output from the internal node, in response to the pull-down control signal; and
a second PMOS transistor increasing a second pull-down current, output from the output node, in response to the pull-down control signal.

12. The level shifter circuit of claim 11, wherein the pull-down drive unit further includes:
a first NMOS transistor having a drain connected to a source of the first PMOS transistor and a gate to which the second voltage is applied;
a second NMOS transistor having a drain connected to a source of the second PMOS transistor and a gate to which the second voltage is applied;
a third NMOS transistor having a drain connected to a source of the first NMOS transistor, a gate receiving the input signal and a source to which the third voltage is applied;
an inverter having an input terminal connected to the gate of the third NMOS transistor and using the first voltage and the third voltage as power source; and
a fourth NMOS transistor having a drain connected to a source of the second NMOS transistor, a gate connected to an output terminal of the inverter and a source to which the third voltage is applied.

13. The level shifter circuit of claim 12, wherein the pull-up drive unit includes:
a third PMOS transistor having a source to which the second voltage is applied, a gate connected to the output node and a drain connected to the internal node; and
a fourth PMOS transistor having a source to which the second voltage is applied, a gate connected to the internal node and a drain connected to the output node.

14. The level shifter circuit of claim 9, wherein the pull-down drive unit comprises:
a first NMOS transistor increasing a first pull-down current, output from the internal node, in response to an external voltage; and
a second NMOS transistor increasing a second pull-down current, output from the output node, in response to the external voltage,
wherein the first voltage is generated based on the external voltage and the second voltage is generated based on the first voltage, and the external voltage is higher than each of the first and second voltages during at least a portion of the operation of the pull-down drive unit.

15. The level shifter circuit of claim 14, wherein the pull-down drive unit further includes:
a third NMOS transistor having a drain connected to a drain of the first NMOS transistor, a gate to which the second voltage is applied and a source connected to a source of the first NMOS transistor;
a fourth NMOS transistor having a drain connected to a drain of the second NMOS transistor, a gate to which the second voltage is applied and a source connected to a source of the second NMOS transistor;
a fifth NMOS transistor having a drain connected to the source of the third NMOS transistor, a gate receiving the input signal and a source to which the third voltage is applied;
an inverter having an input terminal connected to the gate of the fifth NMOS transistor and using the first voltage and the third voltage as a power source; and
a sixth NMOS transistor having a drain connected to the source of the fourth NMOS transistor, a gate connected to an output terminal of the inverter and a source to which the third voltage is applied.

16. The level shifter circuit of claim 15, wherein the pull-up drive unit includes:
a first PMOS transistor having a source to which the second voltage is applied, a gate connected to the output node and a drain connected to the internal node; and
a second PMOS transistor having a source to which the second voltage is applied, a gate connected to the internal node and a drain connected to the output node.

17. A method of level shifting, comprising:
pull-up driving an output node from a first voltage to a second voltage in response to an input signal, a target voltage for the second voltage higher than a target voltage for the first voltage and the input signal based on the first voltage and a third voltage;
pull-down driving the output node to the third voltage in response to the input signal;
determining whether the pull-up and pull-down driving operations are performed concurrently; and
adjusting current levels of at least one of a pull-up current and a pull-down current based on the determining step.

18. The method of claim 17, wherein the third voltage is a ground voltage.

19. The method of claim 17, wherein adjusting the current levels includes reducing the pull-up current if the determining step determines that the pull-up and pull-down driving operations are performed concurrently.

20. The method of claim 17, wherein adjusting the current levels includes increasing the pull-down current if the determining step determines that the pull-up and pull-down driving operations are performed concurrently.
